(19) United States
(12) Patent Application Publication
(10) Pub. No.: US 2022/0400323 A1
(43) Pub. Date: Dec. 15, 2022

(54) ELECTRONIC DEVICE

(71) Applicant: InnoLux Corporation, Miao-Li County (TW)

(72) Inventors: Hsuan-Yin WANG, Miao-Li County (TW); Ming-Han TSAI, Miao-Li County (TW); Chia-Hui CHEN, Miao-Li County (TW)

(21) Appl. No.: 17/745,609

(22) Filed: May 16, 2022

(30) Foreign Application Priority Data
Jun. 15, 2021 (CN) 202110659293.4

(51) Int. Cl. H04R 1/02

(52) U.S. Cl. CPC H04R 1/025

(57) ABSTRACT

An electronic device includes: a housing, a first restraining holder, a second restraining holder and at least one protruding rib structure. The housing includes a first surface. The first restraining holder, the second restraining holder and at least part of the protruding rib structure are arranged on the first surface, and at least part of the protruding rib structure is disposed between the first restraining holder and the second restraining holder.

### CROSS REFERENCE TO RELATED APPLICATION

This application claims the benefits of the Chinese Patent Application Serial Number 202110659293.4, filed on Jun. 15, 2021, the subject matter of which is incorporated herein by reference.

### BACKGROUND

### 1. Field of the Disclosure

The present disclosure relates to an electronic device and, more particularly, to an electronic device with wires inside.

### 2. Description of Related Art

At present, many electronic devices are equipped with sound-generating components. When the sound-generating component generates sound, the vibration generated by the sound-generating component may cause other components inside the electronic device to vibrate, and the components may collide with each other due to the vibration, resulting in unnecessary knocking sound. For example, the wires inside the electronic device may collide with the housing and produce knocking sound, and thus the sound quality may be affected and the components may also be damaged due to collisions.

Therefore, there is a need for a specially designed electronic device to mitigate or obviate the aforementioned problems.

### SUMMARY

The present disclosure provides an electronic device, which includes: a housing, a first restraining holder, a second restraining holder and at least one protruding rib structure. The housing includes a first surface. The first restraining holder, the second restraining holder and at least part of the protruding rib structure are arranged on the first surface, and at least part of the protruding rib structure is disposed between the first restraining holder and the second restraining holder.

Other novel features of the present disclosure will become more apparent from the following detailed description when taken in conjunction with the accompanying drawings.

### BRIEF DESCRIPTION OF THE DRAWINGS

FIG. 1 is a schematic diagram of an electronic device according to some embodiments of the present disclosure;

FIG. 2A is a schematic diagram of a first restraining holder and a second restraining holder according to some embodiments of the present disclosure;

FIG. 2B is a schematic diagram of a protruding rib structure according to some embodiments of the present disclosure;

FIG. 3 is a schematic diagram illustrating the arrangement of the protruding rib structure, and the first restraining holder and the second restraining holder according to some embodiments of the present disclosure;

FIG. 4 is a schematic diagram of a protruding rib structure according to some embodiments of the present disclosure;

FIG. 5 is a schematic diagram of a protruding rib structure according to some embodiments of the present disclosure;

FIG. 6 is a schematic diagram of a protruding rib structure according to some embodiments of the present disclosure;

FIG. 7 is a schematic diagram of a protruding rib structure according to some embodiments of the present disclosure;

FIG. 8 is a schematic diagram of a protruding rib structure according to some embodiments of the present disclosure;

FIG. 9 is a schematic diagram of a protruding rib structure according to some embodiments of the present disclosure; and

FIG. 10 is a schematic diagram illustrating the arrangement of the protruding rib structure, the first restraining holder and the second restraining holder according to some embodiments of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided.

In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method.

In addition, the term “adjacent” used in the specification and claims may refer to describe mutual proximity and does not necessarily mean mutual contact.

In addition, the description of “when . . . ” or “while . . . ” in the present disclosure means “now, before, or after”, etc., and is not limited to occurrence at the same time. In the present disclosure, the similar description of “disposed on” or the like refers to the corresponding positional relationship between the two components, and does not limit whether there is contact between the two components, unless specifically limited. Furthermore, when the present disclosure recites multiple effects, if the word “or” is used between the effects, it means that the effects can exist independently, but it does not exclude that multiple effects can exist at the same time.

In addition, the terms “connect” or “couple” in the specification and claims not only refer to direct connection with another component, but also indirect connection with another component, or refer to electrical connection. Besides, the electrical connection may include a direct connection, an indirect connection, or a mode in which two components communicate through radio signals.

In addition, in the specification and claims, the term “almost”, “about”, “approximately” or “substantially” usually means within 20%, 10%, 5%, 3%, 2%, 1% or 0.5% of a given value or range. The quantity the given value is an approximate quantity, which means that the meaning of “almost”, “about”, “approximately” or “substantially” may still be implied in the absence of a specific description of “almost”, “about”, “approximately” or “substantially”. In addition, the terms “ranging from the first value to the second value” and “range between the first value and the second value” indicate that the range includes the first value, the second value, and other values between the first value and the second value.

In addition, in the specification and claims, the term “or” usually means the aspect including “and” and “or”.

In addition, the technical features of different embodiments disclosed in the present disclosure may be combined to form other embodiments.

In addition, the electronic device disclosed in the present disclosure is an electronic device having a vibration component (such as a sound-generating component, a motor, etc., but not limited thereto), and its implementation may include a display device, an antenna device (or an electronic device with an antenna component), a speaker device, a sensing device, a touch display, a curved display or a free shape display, but it is not limited thereto. For example, the electronic device of the present disclosure may be various electronic devices with sound-generating components. The electronic device may be a bendable or flexible electronic device. The electronic device may include liquid crystal, light emitting diode, fluorescence, phosphor, other suitable display media, or any combination thereof, but it is not limited thereto. The light emitting diodes may include, for example, organic light emitting diodes (OLEDs), sub-millimeter light emitting diodes (mini LEDs), micro light emitting diodes (micro LEDs), or quantum dot (QD) light emitting diodes (such as QLED, QDLED, etc.) or other suitable materials or any combination thereof, but it is not limited thereto. The display device may include, for example, but not limited to, a tiled display device. The antenna device (or the electronic device with the antenna component) may be, for example, but not limited to, a liquid crystal antenna. The antenna device (or the electronic device with the antenna component) may include, for example, but not limited to, a tiled antenna device. It should be noted that, the electronic device may be any arrangement or combination of the foregoing, but it is not limited thereto.

In addition, the appearance of the electronic device may be rectangular, circular, polygonal, a shape with curved edges, or other suitable shapes. The electronic device may have peripheral systems such as a driving system, a control system, a light source system, a shelf system, etc., to support a display device, an antenna device or a tiled device. Hereinafter, for the convenience of description, the display device is used as the electronic device and the sound-generating component is used as the vibration component for description.

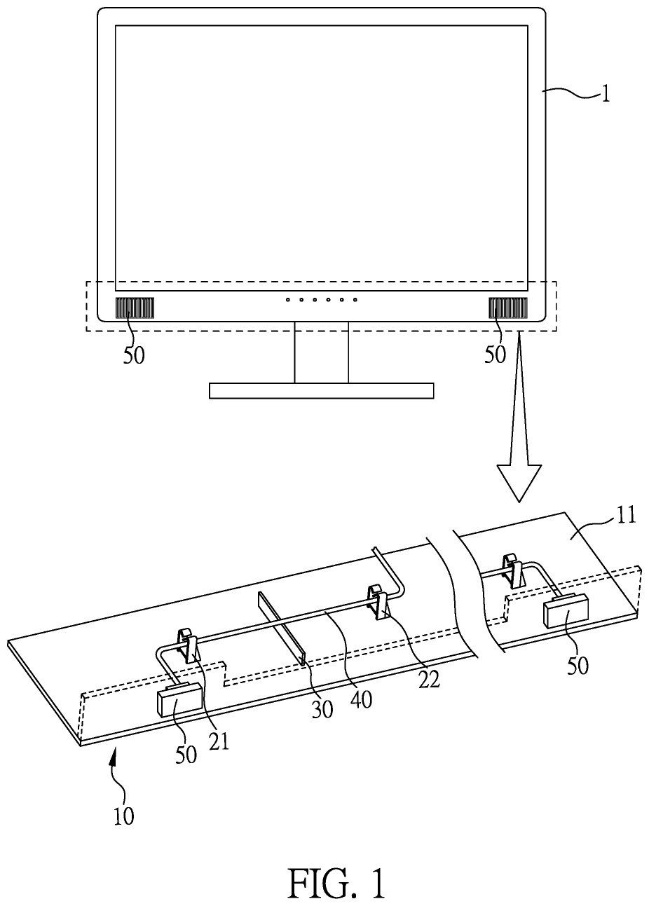

FIG. 1 is a schematic diagram of an electronic device 1 according to some embodiments of the present disclosure. As shown in FIG. 1, the electronic device 1 includes a housing 10, a first restraining holder 21, a second restraining holder 22 and a protruding rib structure 30. The housing 10 includes a first surface 11. The first restraining holder 21 and the second restraining holder 22 are arranged on the first surface 11. At least part of the protruding rib structure 30 is arranged on the first surface 11 and is disposed between the first restraining holder 21 and the second restraining holder 22. In addition, at least one sound-generating component 50 may be arranged on the first surface 11 or on the housing 10.

The first restraining holder 21 may be used to restrain a first portion of a wire 40, the second restraining holder 22 may be used to restrain a second portion of the wire 40, and the protruding rib structure 30 may be used to support the portion of the wire 40 between the first restraining holder 21 and the second restraining holder 22 (hereinafter referred to as a third portion of the wire 40). In some embodiments, the two ends of the wire 40 may be electrically connected to two electronic components inside the electronic device 1, so that signals or power may be transmitted between the electronic components.

As shown in FIG. 1, the third portion of the wire 40 may be supported by the protruding rib structure 30 to be elevated, so that there may be a distance between the wire 40 and the first surface 11. As a result, when the sound-generating component 50 vibrates to cause the wire 40 or the housing 10 to vibrate, the chance of collision between the wire 40 and the housing 10 may be greatly decreased, thereby reducing unnecessary knocking sound.

Next, the details of the housing 10, the first restraining holder 21, the second restraining holder 22, and the protruding rib structure 30 are described.

First, the housing 10 will be described. In some embodiments, the housing 10 may be, for example, a housing of the electronic device 1 or part of the housing, such as a front cover, a back cover, part of the front cover or part of the back cover, but it is not limited thereto. In some embodiments, the material of the housing 10 may include a polymer material (such as plastic, etc.), a metal material (such as pure metal or alloy), or composite material of the foregoing materials, but it is not limited thereto. In addition, as long as being realizable, other materials (such as ceramic materials, etc.) may be used. In some embodiments, when the housing 10 is made of plastic, the type of the plastic may include polyvinyl chloride (PVC), polyethylene (PE), polypropylene (PP), polyurethane (polyurethane, PU), polystyrene (PS), resin, or any combination thereof, but it is not limited thereto. In some embodiments, when the housing 10 is made of metal, the type of the metal may include iron, magnesium, aluminum, copper, tin, lead, steel, gold, silver, or any combination thereof, but it is not limited thereto. In addition, the housing 10 may be a hard housing or a soft housing. In FIG. 1, the housing 10 is, for example, a back cover of a display device, but the present disclosure is not limited thereto.

In some embodiments, the first surface 11 of the housing 10 may be a surface facing the interior of the electronic device 1, but it is not limited thereto. In some embodiments, the first surface 11 of the housing 10 may include the surfaces of the first restraining holder 21 and the second restraining holder 22, but it is not limited thereto. In some embodiments, the first surface 11 of the housing 10 may include the surfaces of the first restraining holder 21, the second restraining holder 22 and the protruding rib structure 30, but it is not limited thereto. In some embodiments, the first surface 11 may be a planar surface, a curved surface, an inclined surface, or a non-planar surface with irregular protrusions or depressions, etc., but it is not limited thereto.

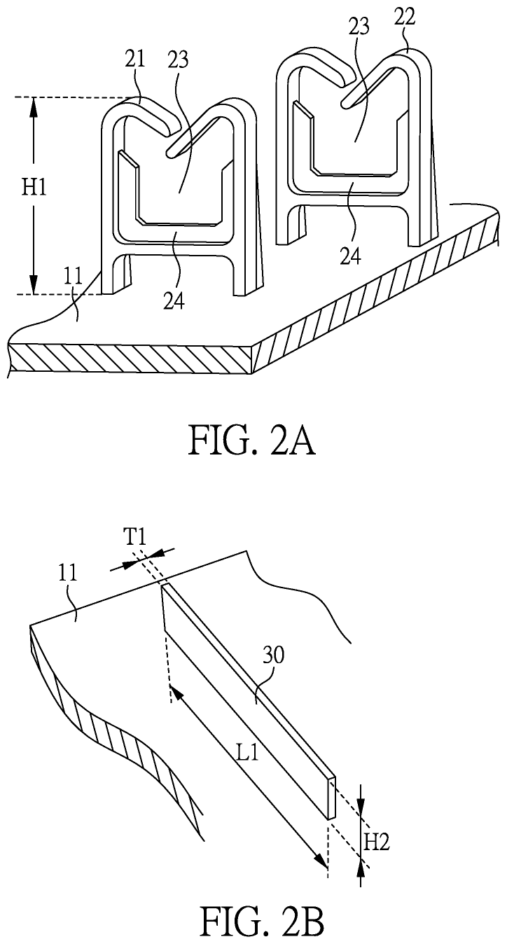

Next, the first restraining holder 21 and the second restraining holder 22 will be described. Please refer to FIG. 1 and FIG. 2A, wherein FIG. 2A is a schematic diagram of the first restraining holder 21 and the second restraining holder 22 in some embodiments of the present disclosure. For the reason of clarity, FIG. 2A shows the first restraining holder 21, the second restraining holder 22 and the first surface 11, which does not mean that other components are excluded. The first restraining holder 21 and the second restraining holder 22 may be used to restrain the position of the wire 40, so that the wire 40 is not easy to slide greatly. As shown in FIG. 2A, the first restraining holder 21 and the second restraining holder 22 each may have a hole 23, wherein the shape and size of the hole 23 may be arbitrarily adjusted according to requirements. The holes 23 may be used for accommodating the wire 40 so that the wire 40 may be restrained in the first restraining holder 21 and the second restraining holder 22. In some embodiments, the size of the hole 23 may be slightly larger than that of the wire 40, so the wire 40 may be tightly fitted into the hole 23. In some embodiments, the size of the hole 23 may be significantly larger than that of the wire 40, so the wire 40 may move in the hole 23, or the hole 23 may accommodate a plurality of wires 40 at the same time. In addition, in some embodiments, the hole 23 of the first restraining holder 21 and the hole 23 of the second restraining holder 22 may be of different sizes or shapes, but it not limited thereto.

In some embodiments, the first restraining holder 21 and/or the second restraining holder 22 may have a height (hereinafter referred to as the first height H1), wherein the first height H1 may be the maximum height of the first restraining holder 21 and/or the second restraining holder 22 in a direction perpendicular to the first surface 11. In some embodiments, the first height H1 may be between 2 and 60 millimeters (i.e., 2 mm≤H1≤60 mm). In some embodiments, the first height H1 may be between 4 and 30 millimeters (i.e., 4 mm≤H1≤30 mm). In some embodiments, the first height H1 may be between 6 and 20 millimeters (i.e., 6 mm≤H1≤20 mm). The above numerical values are only examples, and the present disclosure is not limited thereto.

In some embodiments, the material of the first restraining holder 21 and/or the second restraining holder 22 may include a polymer material (such as plastic, etc.), a metal material (such as pure metal or alloy), or a composite material of the foregoing materials, but it is not limited thereto. In addition, as long as being realizable, other materials (such as ceramic materials, etc.) may also be used. In some embodiments, when the material of the first restraining holder 21 and/or the second restraining holder 22 is plastic, the type of the plastic may include polyvinyl chloride, polyethylene, polypropylene, polyurethane, polystyrene, resin or any combination thereof, but it is not limited thereto. In some embodiments, when the material of the first restraining holder 21 and/or the second restraining holder 22 is metal, the type of the metal may include iron, magnesium, aluminum, copper, tin, lead, steel, gold, silver or any combination thereof, but it is not limited thereto. In some embodiments, the first restraining holder 21 and the second restraining holder 22 may be made of hard material or soft material. In some embodiments, the first restraining holder 21 or the second restraining holder 22 and the housing 10 may be made of the same material. In some embodiments, the first restraining holder 21 or the second restraining holder 22 and the housing 10 may be made of different materials.

In some embodiments, when the material of the first restraining holder 21 or the second restraining holder 22 is the same as that of the housing 10, they can be integrally formed. For example, in some embodiments, when the material of the first restraining holder 21 or the second restraining holder 22 and the material of the housing 10 are both plastic, the first restraining holder 21 or the second restraining holder 22 and the housing 10 may be formed by injection molding, compression molding, extrusion molding, blow molding, inflation molding, vacuum molding, casting molding, etc., but it is not limited thereto. In some embodiments, when the material of the first restraining holder 21 or the second restraining holder 22 and the housing 10 is metal, the first restraining holder 21 or the second restraining holder 22 and the housing 10 may be formed by stamping, metal injection molding, forging, etc., but it is not limited thereto. In some embodiments, when the first restraining holder 21 or the second restraining holder 22 and the housing 10 are not integrally formed, they may also be connected together by means of locking, snapping, bonding, welding, etc., but it is not limited thereto.

In addition, in some embodiments, a buffer member 24 may be arranged in the hole 23. The buffer member 24 may be used to support the wire 40. In addition, when the sound-generating component 50 vibrates, the buffer member 24 may reduce the chance of the wire 40 directly colliding with the first restraining holder 21 and the second restraining holder 22, thereby reducing the impact sound generated between the wire 40 and the first restraining holder 21 and the second restraining holder 22.

In some embodiments, the buffer member 24 may be a rib structure, a U-shaped rib structure, a foam, an elastomer, etc., but it is not limited thereto. In some embodiments, the shape of the buffer member 24 may be adjusted according to the shape of the hole 23. In some embodiments, the material of the buffer member 24 may include a polymer material (such as plastic, etc.), a metal material (such as pure metal or alloy), or a composite material of the foregoing materials, but it is not limited thereto. In addition, as long as being realizable, other materials (such as ceramic materials, foam materials, elastic materials, etc.) may be used. In some embodiments, the buffer member 24 may be a hard buffer member or a soft buffer member. In some embodiments, the buffer member 24 may have different sizes according to different design requirements. For example, when the design requirement is to tightly fix the wire 40 to the hole 23, a buffer member 24 with a larger size can be arranged in the hole 23 (for reducing the free space of the hole 23), but it is not limited thereto.

Next, the protruding rib structure 30 will be described, please refer to FIG. 1 and FIG. 2B, wherein FIG. 2B is a schematic diagram of the protruding rib structure 30 according to some embodiments of the present disclosure. For the reason of clarity, FIG. 2 (B) shows the protruding rib structure 30 and the first surface 11 without meaning that other components are excluded. One end of the protruding rib structure 30 is connected to the first surface 11, and the opposite end thereof may be used to support the wire 40. In addition, in the embodiment of FIG. 2B, the protruding rib structure 30 may be a rectangular structure. For example, the protruding rib structure 30 may be a rectangular body, such as a cuboid, but in other embodiments of the present disclosure, the protruding rib structure 30 may also have different forms, which will be described in the following embodiments.

As shown in FIG. 2B, the protruding rib structure 30 may have a height (hereinafter referred to as the second height H2), wherein the second height H2 may be the maximum height of the protruding rib structure 30 in a direction perpendicular to the first surface 11. In some embodiments, the second height H2 may be between 2 and 60 millimeters (i.e., 2≤mm H2≤60 mm). In some embodiments, the second height H2 may be between 4 and 30 millimeters (i.e., 4 mm≤H2≤30 mm). In some embodiments, the second height H2 may be between 6 and 20 millimeters (i.e., 6 mm≤H2≤20 mm). The above numerical values are only examples, and the present disclosure is not limited thereto.

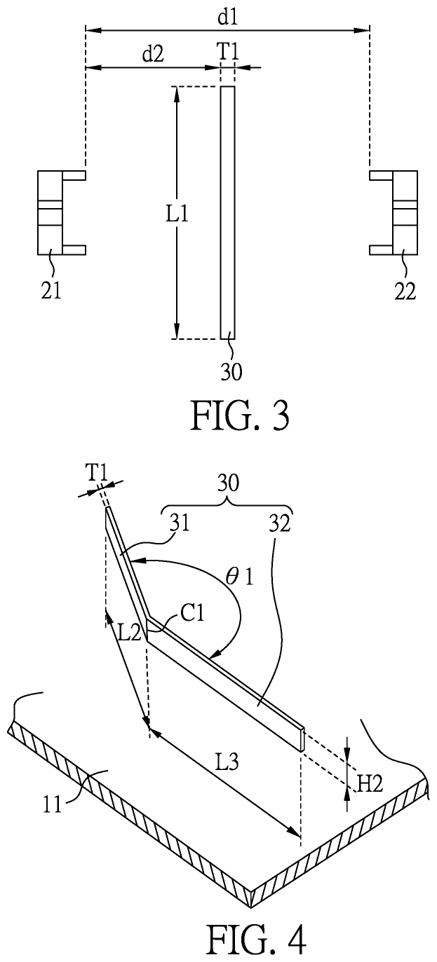

In addition, the protruding rib structure 30 may have a length (hereinafter referred to as the first length L1), wherein the first length L1 may be a maximum length of the protruding rib structure 30 projected onto a projection plane (hereinafter referred to as the first projection plane) in a direction perpendicular to the first surface 11 (please also refer to FIG. 3). In some embodiments, the first length L1 may be between 5 and 200 millimeters (i.e., 5 mm≤L1≤200 mm). The above numerical values are only examples, and the present disclosure is not limited thereto.

In addition, the protruding rib structure may have a width (hereinafter referred to as the first width T1), wherein the first width T1 may be a maximum width of the protruding rib structure 30 projected onto the first projection plane (please also refer to FIG. 3), and the first width T1 may be smaller than the first length L1. In some embodiments, the first width T1 may be between 0.6 and 3 millimeters (i.e., 0.6 mm≤T1≤3 mm). The above numerical values are only examples, and the present disclosure is not limited thereto.

In some embodiments, the material of the protruding rib structure 30 may include a polymer material (such as plastic, etc.), a metal material (such as pure metal or alloy) or a composite material of the foregoing materials, but it is not limited thereto. In addition, as long as being realizable, other materials (such as ceramic materials, etc.) may be used. In some embodiments, when the material of the protruding rib structure 30 is plastic, the type of the plastic may include polyvinyl chloride, polyethylene, polypropylene, polyurethane, polystyrene, resin, or any combination thereof, but it is not limited thereto. In some embodiments, when the material of the protruding rib structure 30 is metal, the type of the metal may include iron, magnesium, aluminum, copper, tin, lead, steel, gold, silver, or any combination thereof, but it is not limited thereto. In some embodiments, the protruding rib structure 30 may be made of a hard material or a soft material. In some embodiments, the protruding rib structure 30 and the housing 10 may be made of the same material. In some embodiments, the protruding rib structure 30, and the first restraining holder 21, the second restraining holder 22 and the housing 10 may be made of the same material.

In some embodiments, when the protruding rib structure 30 and the housing 10 are made of the same material, they can be integrally formed. For example, in some embodiments, when the protruding rib structure 30 and the housing 10 are all made of plastic, the protruding rib structure 30 and the housing 10 may be formed together by methods such as injection molding, compression molding, extrusion molding, bottle blow molding, inflation molding, vacuum molding, and casting molding, but it is not limited thereto. In some embodiments, when the protruding rib structure 30 and the housing 10 are made of the same metal, the protruding rib structure 30 and the housing 10 may be formed together by methods such as stamping molding, metal injection molding, forging, etc., but it is not limited thereto. In addition, when the protruding rib structure 30 and the housing 10 are not integrally formed, they may also be connected together by means of locking, snapping, bonding, welding, etc., but it is not limited thereto.

Next, the arrangement relationship between the protruding rib structure 30 and the first restraining holder 21 or the second restraining holder 22 will be described. FIG. 3 is a schematic diagram illustrating the arrangement of the protruding rib structure 30, and the first restraining holder 21 and the second restraining holder 22 according to some embodiments of the present disclosure, which is presented by projecting the protruding rib structure 30, the first restraining holder 21 and the second restraining holder 22 to the first projection plane. In addition, for the reason of clarity, FIG. 3 shows the protruding rib structure 30, the first restraining holder 21 and the second restraining holder 22, without meaning that other components are excluded.

Please refer to FIG. 3 as well as FIG. 1, FIG. 2A and FIG. 2B as assistance. In some embodiments, there may be a distance (hereinafter referred to as the first distance d1) between the first restraining holder 21 and the second restraining holder 22 projected onto the first projection plane, wherein the first distance d1 may be a shortest distance between the first restraining holder 21 and the second restraining holder 22 on the first projection plane. In some embodiments, the first distance d1 may be between 30 and 300 millimeters (i.e., 30 mm≤d1≤300 mm), but it is not limited thereto. In addition, there may be a distance (hereinafter referred to as the second distance d2) between the protruding rib structure 30 and the first restraining holder 21 or the second restraining holder 22 (at least one of the two) projected onto the first projection plane, wherein the second distance d2 may be a shortest distance between the protruding rib structure 30 and the first restraining holder 21 or the second restraining holder 22 projected onto the first projection plane. In some embodiments, the second distance d2 is between 0.2 times and 0.6 times the first distance d1 (i.e., 0.2*d1≤d2≤0.6*d1), but it is not limited thereto. In some embodiments, the second distance d2 may be between 6 and 180 millimeters (i.e., 6 mm≤d2≤180 mm), and must meet the aforementioned relationship with the first distance d1, but it is not limited thereto.

Therefore, the protruding rib structure 30 may support the third portion of the wire 40, so that the wire 40 is not easy to collide with the first surface 11.

In addition to the rectangular structure in the embodiment of FIG. 2B, the protruding rib structure 30 of the present disclosure may also have different shapes, which will be illustrated below.

FIG. 4 is a schematic diagram of the protruding rib structure 30 according to some embodiments of the present disclosure. In order to highlight the characteristics of the protruding rib structure 30, FIG. 4 shows the protruding rib structure 30 and the first surface 11, which does not mean to exclude other components. Please refer to FIG. 4 as well as FIGS. 1 to 3 as assistance. The protruding rib structure 30 includes a first sub-structure 31 and a second sub-structure 32, wherein the first sub-structure 31 is connected with the second sub-structure 32. For example, the first sub-structure 31 and the second sub-structure 32 may be connected at a connecting location C1. The first sub-structure 31 and the second sub-structure 32 may form an included angle (hereinafter referred to as the first included angle θ1). In other words, the protruding rib structure 30 in the embodiment of FIG. 4 may be regarded as a bending structure, and the connecting location C1 may be regarded as bending location. In some embodiments, the first included angle θ1 may be greater than or equal to 90 degrees and smaller than 180 degrees (i.e., 90 degrees θ1<180 degrees), but it is not limited thereto.

In some embodiments, the first sub-structure 31 and the second sub-structure 32 may be rectangular structures or approximately rectangular structures, but the present disclosure is not limited thereto.

In some embodiments, the first sub-structure 31 has a length (the second length L2), wherein the second length L2 may be the maximum length of the first sub-structure 31 projected onto the first projection plane. In some embodiments, the second sub-structure 32 has a length (the third length L3), wherein the third length L3 may be the maximum length of the second sub-structure 32 projected onto the first projection plane. In some embodiments, the sum of the second length L2 and the third length L3 may be equal to the first length L1 (i.e., L2+L3=L1), but it is not limited thereto. In some embodiments, the sum of the second length L2 and the third length L3 may be greater than the first length L1 (i.e., L2+L3>L1), but it is not limited thereto. In some embodiments, the sum of the second length L2 and the third length L3 may be smaller than the first length L1 (i.e., L2+L3<L1), but it is not limited thereto. The details of the first length L1 can be seen by referring to the description of the embodiment of FIG. 2B.

In addition, in some embodiments, the heights of the first sub-structure 31 and the second sub-structure 32 each may be the second height H2, and the details of the second height H2 can be seen by referring to the description of the embodiment of FIG. 2B. In some embodiments, the widths of the first sub-structure 31 and the second sub-structure 32 each may be the first width T1, and the details of the first width T1 can be seen by referring to the description of the embodiment of FIG. 2B. In addition, when the protruding rib structure 30 is disposed between the first restraining holder 21 and the second restraining holder 22 (as shown in FIG. 1 and FIG. 3), on the first projection plane, the shortest distance between the protruding rib structure 30 and the first restraining holder 21 or the second restraining holder 22 is also the second distance d2, wherein the details of the second distance d2 can be seen by referring to the description of the embodiment of FIG. 3.

Therefore, the protruding rib structure 30 of the embodiment of FIG. 4 can be understood.

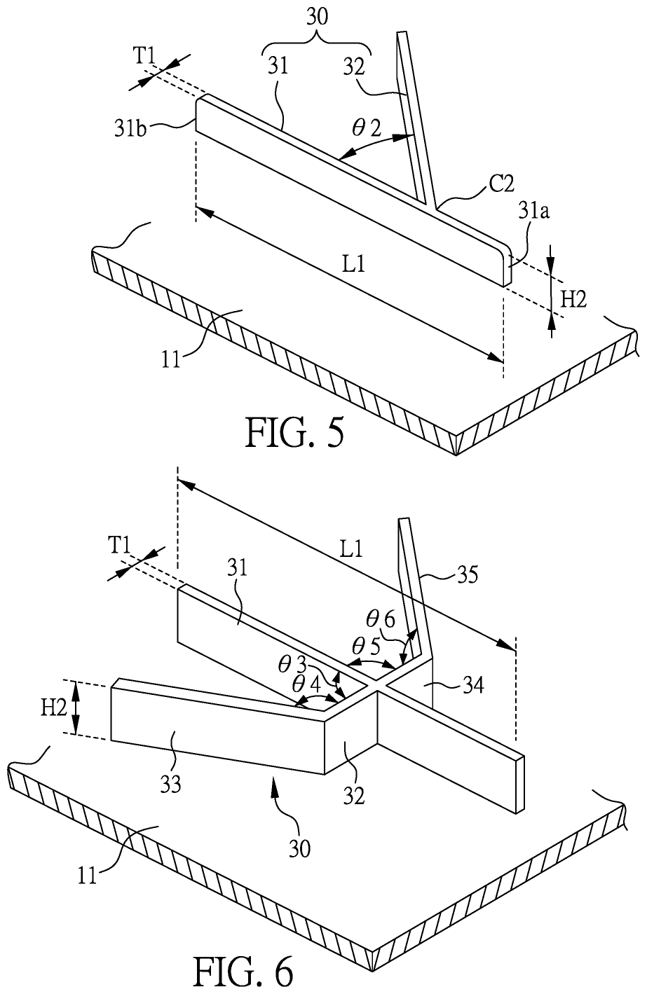

FIG. 5 is a schematic diagram of the protruding rib structure 30 according to some embodiments of the present disclosure, which shows the protruding rib structure 30 and the first surface 11 to highlight the characteristics of the protruding rib structure 30, without meaning to exclude other components. Please refer to FIG. 5 as well as FIGS. 1 to 3 as assistance. The protruding rib structure 30 includes a first sub-structure 31 and a second sub-structure 32, wherein the second sub-structure 32 may extend from a connecting location C2 on the first sub-structure 31 in a direction away from the first sub-structure 31, and the connecting location C2 is not disposed at the two ends 31a and 31b of the first sub-structure 31. An included angle (hereinafter referred to as the second included angle θ2) may be formed between the first sub-structure 31 and the second sub-structure 32. In some embodiments, the second angle θ2 may be greater than 0 degrees and smaller than or equal to 90 degrees (0 degrees<θ2≤90 degrees). The above numerical values are only examples, and the present disclosure is not limited thereto.

In some embodiments, the first sub-structure 31 and the second sub-structure 32 may be rectangular structures or approximately rectangular structures, but the present disclosure is not limited thereto.

In some embodiments, the length of the first sub-structure 31 may be the first length L1, wherein the details of the first length L1 can be seen by referring to the description of the embodiment of FIG. 2B. In some embodiments, the heights of the first sub-structure 31 and the second sub-structure 32 each may be the second height H2, and the details of the second height H2 can be seen by referring to the description of the embodiment of FIG. 2B. In some embodiments, the widths of the first sub-structure 31 and the second sub-structure 32 each may be the first width T1, and the details of the first width T1 can be seen by referring to the description of the embodiment of FIG. 2B. In addition, when the protruding rib structure 30 is disposed between the first restraining holder 21 and the second restraining holder 22 (as shown in FIG. 1 and FIG. 3), on the first projection plane, the distance between the protruding rib structure 30 and the first restraining holder 21 or the second restraining holder 22 is also the second distance d2, wherein the details of the second distance d2 can be seen by referring to the description of the embodiment of FIG. 3.

Therefore, the protruding rib structure 30 of the embodiment of FIG. 5 can be understood.

FIG. 6 is a schematic diagram of the protruding rib structure 30 according to some embodiments of the present disclosure, which shows the protruding rib structure 30 and the first surface 11 to highlight the characteristics of the protruding rib structure 30, without meaning to exclude other components. Please refer to FIG. 6 as well as FIGS. 1 to 3 as assistance, the protruding rib structure 30 includes a first sub-structure 31, a second sub-structure 32, a third sub-structure 33, a fourth sub-structure 34 and a fifth sub-structure 35, wherein one end of the second sub-structure 32 may be connected to the first sub-structure 31 and the other end of the second sub-structure 32 may be connected to the third sub-structure 33, and one end of the fourth sub-structure 34 may be connected to the first sub-structure 31 and the other end of the fourth sub-structure 34 may be connected to the fifth sub-structure 35.

In some embodiments, the first sub-structure 31, the second sub-structure 32, the third sub-structure 33, the fourth sub-structure 34 and the fifth sub-structure 35 may be rectangular structures or approximately rectangular structures, but the present disclosure is not limited thereto.

An included angle (hereinafter referred to as the third included angle θ3) may be formed between the first sub-structure 31 and the second sub-structure 32. In some embodiments, the third included angle θ3 may be 90 degrees (i.e., θ3=90 degrees), but it is not limited thereto. An included angle (hereinafter referred to as the fourth included angle θ4) may be formed between the second sub-structure 32 and the third sub-structure 33. In some embodiments, the fourth included angle θ4 may be greater than or equal to 90 degrees (i.e., θ4≥90 degrees), but it is not limited thereto. An included angle (hereinafter referred to as the fifth included angle θ5) may be formed between the first sub-structure 31 and the fourth sub-structure 34. In some embodiments, the fifth included angle θ5 may be 90 degrees (i.e., θ5=90 degrees), but it is not limited thereto. An included angle (hereinafter referred to as the sixth included angle θ6) may be formed between the fourth sub-structure 34 and the fifth sub-structure 35. In some embodiments, the sixth angle θ6 may be greater than or equal to 90 degrees (i.e., θ6≥90 degrees), but it is not limited thereto. The above numerical values are only examples, and the present disclosure is not limited thereto.

In some embodiments, the second and third sub-structures 32 and 33 and the fourth and fifth sub-structures 34 and 35 may be symmetrically arranged on two sides of the first sub-structure 31, for example, disposed in a mirrored arrangement by taking the sub-structure 31 as a reference. At this moment, the second sub-structure 32 and the fourth sub-structure 34 may be connected to the same line length location of the first sub-structure 31 and respectively extend to two sides of the first sub-structure 31, and the third included angle θ3 may be equal to the fifth included angle θ5 and the fourth included angle θ4 may be equal to the sixth included angle θ6, but the present disclosure is not limited thereto. However, in some embodiments, the third included angle θ3 may be different from the fifth included angle θ5, and the fourth included angle θ4 may be different from the sixth included angle θ6. In addition, in some embodiments, the dimensions of the second sub-structure 32 and the fourth sub-structure 34 may be the same or different, and the dimensions of the third sub-structure 33 and the fifth sub-structure 35 may be the same or different. The present disclosure is not limited thereto.

In some embodiments, the length of the first sub-structure 31 may be the first length L1, wherein the details of the first length L1 can be seen by referring to the description of the embodiment of FIG. 2B. In some embodiments, the heights of the first sub-structure 31, the second sub-structure 32, the third sub-structure 33, the fourth sub-structure 34 and the fifth sub-structure 35 each may be the second height H2, wherein the details of the second height H2 can be seen by referring to the description of the embodiment of FIG. 2B. In some embodiments, the widths of the first sub-structure 31, the second sub-structure 32, the third sub-structure 33, the fourth sub-structure 34 and the fifth sub-structure 35 each may be the first width T1, wherein the details of the first width T1 can be seen by referring to the description of the embodiment of FIG. 2B. In addition, when the protruding rib structure 30 is disposed between the first restraining holder 21 and the second restraining holder 22 (as shown in FIG. 1 and FIG. 3), on the first projection plane, the shortest distance between the protruding rib structure 30 and the first restraining holder 21 or the second restraining holder 22 is also the second distance d2, wherein the details of the second distance d2 can be seen by referring to the description of the embodiment of FIG. 3.

Therefore, the embodiment of FIG. 6 can be understood.

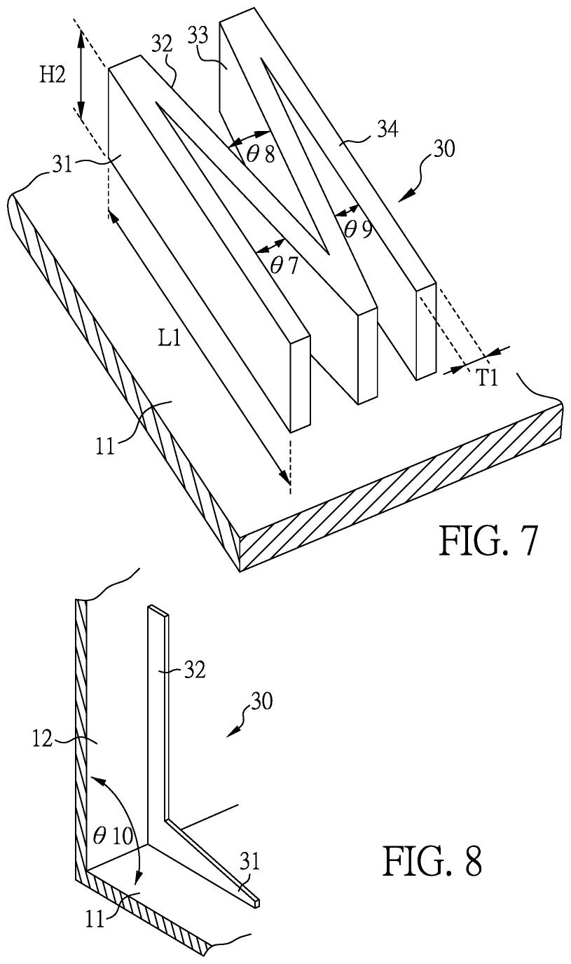

FIG. 7 is a schematic diagram of the protruding rib structure 30 according to some embodiments of the present disclosure, which shows the protruding rib structure 30 and the first surface 11 to highlight the characteristics of the protruding rib structure 30, without meaning to exclude other components. Please refer to FIG. 7 as well as FIGS. 1 to 3 as assistance. The protruding rib structure 30 includes a first sub-structure 31, a second sub-structure 32, a third sub-structure 33 and a fourth sub-structure 34, wherein one end of the second sub-structure 32 is connected to one end of the first sub-structure 31, the other end of the second sub-structure 32 is connected to one end of the third sub-structure 33, and the other end of the third sub-structure 33 is connected to one end of the fourth sub-structure 34. In some embodiments, the protruding rib structure 30 may be an M-shaped structure or an approximately M-shaped structure, but the present disclosure is not limited thereto.

In some embodiments, the first sub-structure 31, the second sub-structure 32, the third sub-structure 33 and the fourth sub-structure 34 may be rectangular structures or approximately rectangular structures, but the present disclosure is not limited thereto.

An included angle (hereinafter referred to as the seventh included angle θ7) may be formed between the first sub-structure 31 and the second sub-structure 32. In some embodiments, the seventh included angle θ7 may be smaller than 90 degrees (θ7<90 degrees). An included angle (hereinafter referred to as the eighth included angle θ8) may be formed between the second sub-structure 32 and the third sub-structure 33. In some embodiments, the eighth included angle θ8 may be smaller than 90 degrees (θ8<90 degrees). An included angle (hereinafter referred to as the ninth included angle θ9) may be formed between the third sub-structure 33 and the fourth sub-structure 34. In some embodiments, the ninth included angle θ9 may be smaller than 90 degrees (θ9<90 degrees). In some embodiments, the seventh included angle θ7, the eighth included angle θ8 and the ninth included angle θ9 may be the same or different. The above numerical values are only examples, and the present disclosure is not limited thereto.

In some embodiments, the length of the first sub-structure 31 or the fourth sub-structure 34 may be the first length L1, and the details of the first length L1 can be seen by referring to the description of the embodiment of FIG. 2B. In some embodiments, the heights of the first sub-structure 31, the second sub-structure 32, the third sub-structure 33 and the fourth sub-structure 34 each may be the second height H2, and the details of the second height H2 can be seen by referring to the description of the embodiment of FIG. 2B. In some embodiments, the widths of the first sub-structure 31, the second sub-structure 32, the third sub-structure 33 and the fourth sub-structure 34 each may be the first width T1, and the details of the first width T1 can be seen by referring to the description of the embodiment of FIG. 2B. In addition, when the protruding rib structure 30 is disposed between the first restraining holder 21 and the second restraining holder 22 (as shown in FIG. 1 and FIG. 3), on the first projection plane, the shortest distance between the protruding rib structure 30 and the first restraining holder 22 or the second restraining holder 22 is also the second distance d2, and the details of the second distance d2 can be seen by referring to the description of the embodiment of FIG. 3.

Therefore, the embodiment of FIG. 7 can be understood.

One of the features of the embodiments of FIG. 4 to FIG. 7 is that the protruding rib structure 30 may simultaneously support more than two wires 40 or wires 40 between multiple restraining holders. For example, when using three restraining holders to restrain more than two wires 40, the structures of the embodiments of FIG. 4 to FIG. 7 may be used to support more than two wires 40 at the same time according to requirements, so that the configuration of the wires 40 is more flexible. However, the present disclosure is not limited thereto.

Therefore, the non-rectangular structures of the embodiments of FIGS. 4 to 7 can be understood.

FIG. 8 is a schematic diagram of the protruding rib structure 30 according to some embodiments of the present disclosure, which shows the protruding rib structure 30, the first surface 11 and a second surface 12 to highlight the characteristics of the protruding rib structure 30, without meaning to exclude the other components. Please refer to FIG. 8 as well as FIGS. 1 to 3 as assistance. In the embodiment of FIG. 8, the housing 10 includes the first surface 11 and the second surface 12, wherein the second surface 12 is connected to the first surface 11, and an included angle (hereinafter referred to as the tenth included angle θ10) may be formed therebetween. The protruding rib structure 30 may include a first sub-structure 31 and a second sub-structure 32, wherein the first sub-structure 31 is disposed on the first surface 11, the second sub-structure 32 is disposed on the second surface 12, and the first sub-structure 31 is connected to the second sub-structure 32.

In some embodiments, the tenth angle θ10 may be greater than 0 degrees and smaller than 180 degrees (i.e., 0 degrees<θ10<180 degrees). In some embodiments, the tenth angle θ10 may be greater than or equal to 90 degrees and smaller than 180 degrees (i.e., 90 degrees≤θ10<180 degrees). In some embodiments, the tenth included angle θ10 may be greater than 0 degrees and smaller than or equal to 90 degrees (i.e., 0 degrees<θ10 90 degrees). The above numerical values are only examples, and the present disclosure is not limited thereto.

In some embodiments, the first sub-structure 31 or the second sub-structure 32 may be a rectangular structure as in the embodiment of FIG. 2B, but may also be other shapes. In addition, the shapes of the first sub-structure 31 and the second sub-structure 32 may be the same or different.

In some embodiments, the length, height and width of the first sub-structure 31 or the second sub-structure 32 may be suitable for the description of the embodiment of FIG. 2B, but the present disclosure is not limited thereto. In addition, when the protruding rib structure 30 is disposed between the first restraining holder 21 and the second restraining holder 22 (as shown in FIG. 1 and FIG. 3), and the first restraining holder 21 and the second restraining holder 22 are disposed on the first surface 11, on the first projection plane, the shortest distance between the protruding rib structure 30 and the first restraining holder 21 or the second restraining holder 22 is also the second distance d2, and the details of the second distance d2 can be seen by referring to the description of the embodiment of FIG. 3.

One of the features of the structure of the embodiment shown in FIG. 8 is that the protruding rib structure 30 may be used to support the wire 40 disposed at the bent portion of the housing 10 (for example, the connecting location between the first surface 11 and the second surface 12), so that the wire 40 is not likely to collide with the bent portion of the housing 10.

However, the present disclosure is not limited thereto.

Therefore, the embodiment of FIG. 8 can be understood.

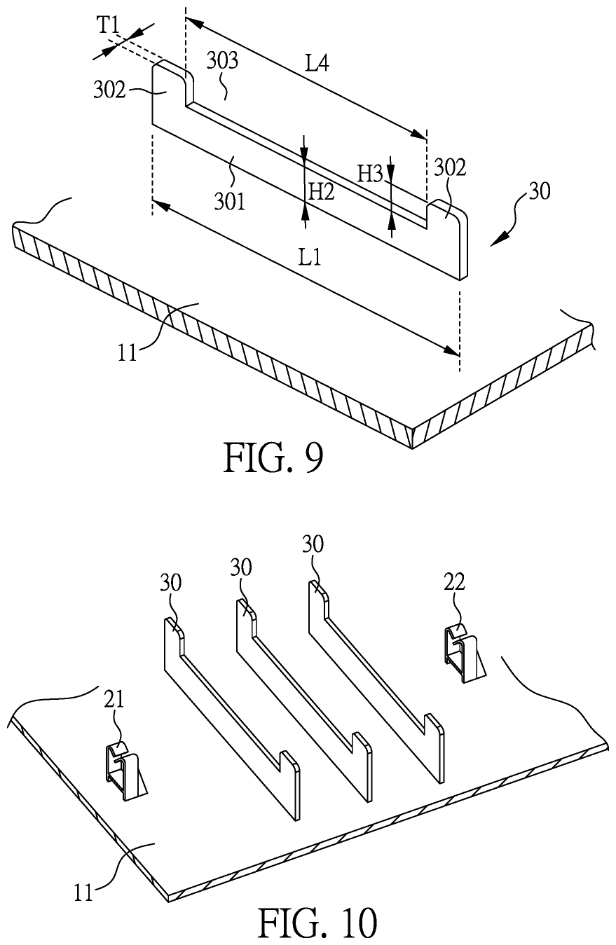

FIG. 9 is a schematic diagram of the protruding rib structure 30 according to some embodiments of the present disclosure, which shows the protruding rib structure 30 and the first surface 11 to highlight the characteristics of the protruding rib structure 30, without meaning to exclude other components. Please refer to FIG. 9 with FIGS. 1 to 3 as assistance, the protruding rib structure 30 can be an approximately U-shaped structure, and includes a main body 301 and two extension portions 302, wherein the two extension portions 302 are respectively connected to the two ends of the main body 301, and extend along a direction perpendicular to the first surface 11 thereby forming the groove 303. In some embodiments, the main body 301 may be a rectangular structure.

In some embodiments, the length of the main body 301 may be the first length L1, and the details of the first length L1 can be seen by referring to the description of the embodiment of FIG. 2B. In some embodiments, the groove 303 has a length (hereinafter referred to as the fourth length L4), wherein the fourth length L4 may be the maximum length of the groove 303 projected onto the first projection plane. In some embodiments, the fourth length L4 may be between 1 and 198 millimeters (i.e., 1 mm≤L4≤198 mm), but it is not limited thereto. Furthermore, the fourth length L4 is smaller than the first length L1 (i.e., L4<L1).

The groove 303 may have a height (hereinafter referred to as the third height H3), wherein the third height H3 may be the maximum height of the groove 303 in a direction perpendicular to the first surface 11, that is, the extension height of the two extension portions 302. In some embodiments, the third height H3 may be between 2 and 60 millimeters (i.e., 2 mm≤H3≤60 mm). In some embodiments, the third height H3 may be between 4 and 30 millimeters (i.e., 4 mm≤H3≤30 mm). In some embodiments, the third height H3 may be between 6 and 20 millimeters (i.e., 6 mm≤H3≤20 mm). However, the present disclosure is not limited thereto.

In some embodiments, the main body 301 has a second height H2, and the details of the second height H2 can be seen by referring to the description of the embodiment of FIG. 2B. Furthermore, in some embodiments, the second height H2 and the third height H3 may be the same or different.

In some embodiments, the width of the main body 301, the extension portion 302 and the groove 303 may be the first width T1, and the details of the first width T1 can be seen by referring to the description of the embodiment of FIG. 2B. In addition, when the protruding rib structure 30 is disposed between the first restraining holder 21 and the second restraining holder 22 (as shown in FIG. 1 and FIG. 3), on the first projection plane, the shortest distance between the protruding rib structure 30 and the first restraining holder 21 or the second restraining holder 22 is also the second distance d2, and the details of the second distance d2 can be seen by referring to the description of the embodiment of FIG. 3.

One of the features of the embodiment of FIG. 9 is that the wire 40 may be restrained in the groove 303 and thus is not likely to escape from the protruding rib structure 30, but it is not limited thereto.

Therefore, the embodiment of FIG. 9 can be understood.

It is noted that, although FIGS. 1 and 4 to 9 show various aspects of the protruding rib structure 30, the present disclosure is not limited thereto, and the protruding rib structure 30 may also have more different aspects.

The arrangement of the protruding rib structure 30 and the first restraining holder 21 and the second restraining holder 22 may also have different implementations. For the reason of clarity, the figures show the protruding rib structure 30, the first restraining holder 21 and the second restraining holder 22, and the first surface 11 without meaning to exclude other components. FIG. 10 is a schematic diagram illustrating the arrangement of the protruding rib structure 30, the first restraining holder 21 and the second restraining holder 22 according to some embodiments of the present disclosure. Please refer to FIG. 10 as well as FIGS. 1 to 9 as assistance. In this embodiment, a plurality of protruding rib structures 30 may be disposed between the first restraining holder 21 and the second restraining holder 22.

In some embodiments, the shapes of the plurality of protruding rib structures 30 may be in consistency. For example, the shapes of the plurality of protruding rib structures 30 may all be the shape of the same embodiment in the aforementioned embodiments, for example, the approximately U-shaped structure of the embodiment of FIG. 9, but it is not limited thereto. In some embodiments, the shapes of the plurality of protruding rib structures 30 may be in inconsistency, for example, some may be the rectangular structures in the embodiment of FIG. 2B, and some may be approximately U-shaped structures in the embodiment of FIG. 9, but it is not limited thereto.

In addition, as long as the wire 40 can be supported, the arrangement of the plurality of protruding rib structures 30 is not limited. For example, the plurality of protruding rib structures 30 may be aligned along the same direction, or may not be aligned. The present disclosure is not limited thereto. In addition, on the first projection plane, the shortest distance between each protruding rib structure 30 and the first restraining holder 21 or the second restraining holder 22 may also be the second distance d2, and the details of the second distance d2 can be seen by referring to the description of the embodiment of FIG. 3. It is noted that, the distance between each protruding rib structure 30 and the first restraining holder 21 or the second restraining holder 22 may be different, but all distances must satisfy the aforementioned condition of the second distance d2.

One of the features of the embodiment of FIG. 10 is that the protruding rib structure 30 may support the wire 40 with a longer length, but it is not limited thereto.

Therefore, the embodiment of FIG. 10 can be understood.

In some embodiments, the electronic device 1 manufactured in the aforementioned embodiments may be used as a touch device with a sound-generating function. Furthermore, if the electronic device 1 manufactured in the aforementioned embodiments of the present disclosure is in the form of a display device or a touch display device with a sound-generating function, it may be applied to any products known in the art that have a sound-generating function and require a display device to display images, such as monitors, mobile phones, notebook computers, camcorders, cameras, music players, mobile navigation devices, television sets, car dashboards, center consoles, electronic rearview mirrors, head-up displays, etc.

In some embodiments, the patent protection scope of the present disclosure may be known at least directly through observation of mechanism, for example, by comparing the presence or absence of components in the electronic device or the arrangement relationship of the components as proof of whether the object falls within the scope of patent protection, but it is not limited thereto.

As a result, the present disclosure provides an improved electronic device, in which the arrangement of the protruding rib structure may reduce the chance of collision between the wire and the housing when the sound-generating component vibrates, thereby reducing unnecessary noise.

The features of the embodiments disclosed in the present disclosure may be mixed and matched arbitrarily as long as they do not violate the spirit of the invention or conflict with each other.

The aforementioned specific embodiments should be construed as merely illustrative, and not limiting the rest of the present disclosure in any way.

What is claimed is:

1. An electronic device, comprising:
a housing having a first surface;
a first restraining holder arranged on the first surface;
a second restraining holder arranged on the first surface; and
at least one protruding rib structure, wherein at least part of the at least one protruding rib structure is arranged on the first surface, and is disposed between the first restraining holder and the second restraining holder.

2. The electronic device of claim 1, wherein the first restraining holder or the second restraining holder has a first height, and the first height is between 2 millimeters and 60 millimeters.

3. The electronic device of claim 1, wherein the at least one protruding rib structure has a second height, and the second height is between 2 millimeters and 60 millimeters.

4. The electronic device of claim 1, wherein a shortest distance between the first restraining holder and the second restraining holder is a first distance, and a shortest distance between the at least one protruding rib structure and the first restraining holder or the second restraining holder is a second distance, wherein the second distance is between 0.2 times and 0.6 times the first distance.

5. The electronic device of claim 4, wherein the first distance is between 30 millimeters and 300 millimeters.

6. The electronic device of claim 1, wherein the at least one protruding rib structure includes a first sub-structure and a second sub-structure, and the first sub-structure and the second sub-structure are connected to form a first included angle.

7. The electronic device of claim 1, wherein the at least one protruding rib structure includes a first sub-structure and a second sub-structure, and the housing includes a second surface connected to the first surface, and wherein the first sub-structure is arranged on the first surface, and the second sub-structure is arranged on the second surface.

8. The electronic device of claim 1, wherein the at least one protruding rib structure includes a groove.

9. The electronic device of claim 1, wherein the at least one protruding rib structure includes a plurality of protruding rib structures.

10. The electronic device of claim 1, wherein the first restraining holder or the second restraining holder includes a hole and a buffer member, and the buffer member is arranged in the hole.

11. The electronic device of claim 6, wherein the first included angle is greater than or equal to 90 degrees and smaller than 180 degrees.

12. The electronic device of claim 6, wherein the first sub-structure and the second sub-structure are rectangular structures.

13. The electronic device of claim 1, wherein the at least one protruding rib structure includes a first sub-structure and a second sub-structure, the second sub-structure extends from a connecting location on the first sub-structure in a direction away from the first sub-structure, the connecting location is not disposed at two ends of the first sub-structure, and a second included angle is formed between the first sub-structure and the second sub-structure.

14. The electronic device of claim 13, wherein the second included angle is greater than 0 degrees and smaller than or equal to 90 degrees.

15. The electronic device of claim 1, wherein the protruding rib structure includes a first sub-structure, a second sub-structure, a third sub-structure, a fourth sub-structure and a fifth sub-structure structure, one end of the second sub-structure is connected to the first sub-structure and the other end of the second sub-structure is connected to the third sub-structure, and one end of the fourth sub-structure is connected to the first sub-structure and the other end of the fourth sub-structure is connected to the fifth sub-structure; wherein a third included angle is formed between the first sub-structure and the second sub-structure, a fourth included angle is formed between the second sub-structure and the third sub-structure, a fifth included angle is formed between the first sub-structure and the fourth sub-structure, and a sixth included angle is formed between the fourth sub-structure and the fifth sub-structure.

16. The electronic device of claim 15, wherein the third included angle is 90 degrees, the fourth included angle is greater than or equal to 90 degrees, the fifth included angle is 90 degrees, and the sixth included angle is greater than or equal to 90 degrees.

17. The electronic device of claim 1, wherein the protruding rib structure includes a first sub-structure, a second sub-structure, a third sub-structure and a fourth sub-structure, in which one end of the second sub-structure is connected to one end of the first sub-structure, the other end of the second sub-structure is connected to one end of the third sub-structure, and the other end of the third sub-structure is connected to one end of the fourth sub-structure; wherein a seventh included angle is formed between the first sub-structure and the second sub-structure, an eighth angle is formed between the second sub-structure and the third sub-structure, and a ninth included angle is formed between the third sub-structure and the fourth sub-structure.

18. The electronic device of claim 17, wherein the seventh included angle is smaller than 90 degrees, the eighth included angle is smaller than 90 degrees, and the ninth included angle is smaller than 90 degrees.

19. The electronic device of claim 7, wherein the second surface is connected to the first surface, a tenth included angle is formed between the first surface and the second surface, and the tenth included angle is greater than 0 degrees and smaller than 180 degrees.

20. The electronic device of claim 7, wherein the first sub-structure and the second sub-structure are rectangular structures.
